(19) United States
(12) Patent Application Publication
(10) Pub. No.: US 2003/0145883 A1
(43) Pub. Date: Aug. 7, 2003

(54) Gravity induced temperature difference device

(76) Inventor: Roderich W. Graeff, Ithaca, NY (US)

Correspondence Address: BROWN & MICHAELS, PC, 400 M & T BANK BUILDING, 118 NORTH TIOGA ST, ITHACA, NY, 14850, US

(21) Appl. No.: 10/351,946

(22) Filed: Jan. 27, 2003

Related U.S. Application Data
(60) Provisional application No. 60/353,307, filed on Feb. 1, 2002.

(51) Int. Cl. F28F 7/00; H01L 35/34

(52) U.S. Cl. 136/201; 165/138

(57) ABSTRACT

A method and apparatus for creating temperature differences in columns of gases, liquids or solids in a closed system under the influence of gravity is used to provide energy in the form of electricity or heat. A temperature differential element, optionally a solid, liquid or gas, is suspended vertically in a chamber inside an enclosure. The chamber optionally is either evacuated, filled with fibers, powder or small spheres, or otherwise arranged to minimize the effects of convection currents and radiation. Under the effect of gravity, the upper end of the temperature differential element becomes cooler than the lower end. A thermocouple can be used to generate electrical energy from the temperature difference between a vertical segment, for example the upper and lower ends, of the temperature differential element, or heat exchangers used to extract heat.

### REFERENCE TO RELATED APPLICATIONS

This application claims an invention which was disclosed in Provisional Application No. 60/353,307, filed Feb. 1, 2002, entitled “GRAVITY INDUCED TEMPERATURE DIFFERENCE DEVICE”. The benefit under 35 USC §119(e) of the U.S. provisional application is hereby claimed, and the aforementioned application is hereby incorporated herein by reference.

### BACKGROUND OF THE INVENTION

1. Field of the Invention

The present invention pertains to the field of energy production. More particularly, the invention pertains to a method and apparatus for creating temperature differences in columns of gases, liquids or solids in a closed system under the influence of gravity, and using the temperature differential to extract useful energy.

2. Description of Related Art

Of all processes that are permitted by the first law of thermodynamics, such as energy conversions, only certain types of processes actually occur in nature. It is the second law of thermodynamics that determines whether a process will or will not occur. Examples of such processes include, but are not limited to heat flow from a warmer to a cooler body, the spontaneous dissolution of salt in water, and the decrease in amplitude of the oscillations of a pendulum over time. These are examples of “irreversible” processes, or processes that occur naturally in one direction only, otherwise requiring the input of energy or work. In general, a process is irreversible if the system and its surroundings cannot return spontaneously to their initial states. Such processes can only be returned to their initial states by changing the surroundings, or doing external work.

The second law of thermodynamics can be stated in numerous ways. The Kelvin-Planck form of the second law states that no heat engine operating in a cycle can absorb thermal energy from a reservoir and perform an equal amount of work. Alternatively, in the words of Rudolf Clausius, it is impossible to construct a cyclical machine that produces no other effect than to transfer heat continuously from one body to another body at a higher temperature. Although these statements may appear to be unrelated, they are in fact equivalent. In essence, the second law states that a device capable of converting thermal energy into other forms of energy at 100% efficiency cannot be constructed.

A closed system in the field of thermodynamics is defined as an enclosed region of constant volume, wherein neither mass nor energy crosses the boundary. Inside the enclosed region, in accordance with the second law of thermodynamics:

initial temperature differences will become smaller and temperatures will eventually equalize, meaning that the entropy will increase;

heat will not flow from a cooler to a hotter object; and

no process can take place where the entropy would decrease.

In other words, the second law of thermodynamics states that, in a closed system, real processes occur in only one preferred direction. Thus, heat flows spontaneously from a warmer object to a cooler one, while the reverse reaction does not occur spontaneously, but rather requires the input of work or energy.

### SUMMARY OF THE INVENTION

In accordance with the invention, it was found that it is possible within the right apparatus to create temperature differences in a closed system without introducing work and thereby to decrease the entropy. The temperature differences so produced can be used to perform work outside the closed system.

The present invention is a method and apparatus for creating temperature differences in columns of gases, liquids or solids in a closed system under the influence of gravity. The temperature differences can be used to provide energy in the form of electricity or heat. The invention also pertains to apparatus for reducing temperature influences from outside the closed system.

In an embodiment of the invention, a temperature differential element, optionally a solid, liquid or gas, is suspended vertically in a chamber inside an enclosure. The chamber optionally is either evacuated, filled with fibers, powder or small spheres, or otherwise arranged to minimize the effects of convection currents. Under the effect of gravity, the upper end of the temperature differential element becomes cooler than the lower end. A thermocouple can be used to generate electrical energy from the temperature difference between a vertical segment, for example the upper and lower ends, of the temperature differential element.

### BRIEF DESCRIPTION OF THE DRAWINGS

FIG. 1 shows an apparatus demonstrating the method of the invention.

FIG. 2 shows another embodiment of the invention, using a metal rod as the temperature differential element.

FIG. 3 shows still another embodiment of the invention, in which the chamber is in a vacuum instead of being gas-filled.

FIG. 4 shows another embodiment of the invention, in which the chamber is divided by a number of horizontally arranged thin films.

FIG. 5 shows an optional apparatus for reducing the temperature influence from outside the closed system, according to an embodiment of the invention.

FIG. 6 shows another optional apparatus, wherein a Dewar glass is used for reducing the temperature influence from outside the closed system and heat exchangers extract energy, according to an embodiment of the invention.

FIG. 7 shows an arrangement of apparatus to reach higher temperature differences.

FIG. 8 is a section along the line 8-8 in FIG. 5.

### DETAILED DESCRIPTION OF THE INVENTION

The method of the invention comprises the step of exposing atoms or molecules to the effects of gravity in a closed system in a vertical arrangement.

Due to the tendency of warm air to rise and of cold air to flow downwards, a room filled with air, either heated or cooled, typically has a higher temperature in the upper parts than in the lower parts. Typically, the temperature distribution over the height is on the order of about 1 degree C. per meter. One would therefore assume that, even when very well insulated from the surroundings, lead rod 1, as shown in FIG. 2, would have a higher temperature at the top than at the bottom. However, to the contrary, once equilibrium is reached, lead rod 1 actually has a colder temperature at the top than at the bottom. The method of the present invention is based upon this unexpected observation.

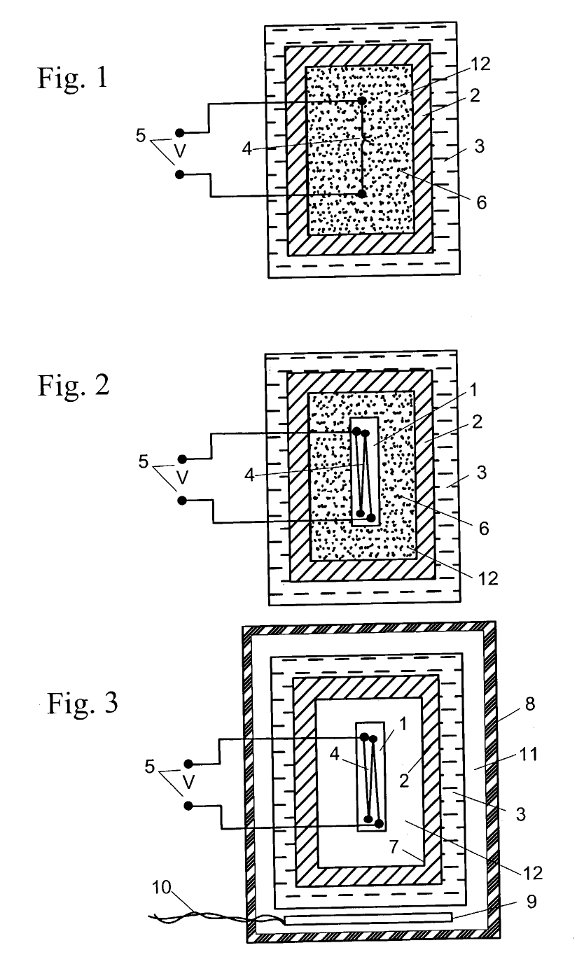

Referring to FIG. 1, when an elongated container 2 containing a gas (such as, e.g., air) is placed in a vertical position, the air molecules move randomly within the container in a movement called “Brownian Motion”. However, even a closed system is exposed to the effects of gravity. Therefore, any molecule moving in an upward direction will be slowed down, and any molecule moving downward will be accelerated by the force of gravity. This means that molecules in the upper part of the container will have, on average, a slower speed (i.e., less kinetic energy) than molecules in the lower part. The temperature of a number of molecules (e.g., a gas) is proportional to the average velocity or kinetic energy of the molecules. Therefore, the temperature in the upper part of the container is lower than the temperature in the lower part. By hitting the upper and lower wall, the molecules attain the temperatures of the walls, cooling the upper walls and heating the lower walls. Thus, energy is transported from the upper walls to the lower walls, thereby creating a lower temperature in the upper walls and a higher temperature in the lower walls. This temperature difference is used in the present invention to perform work inside or outside the closed system.

In fluids, whether liquids or, in particular, gases, warmer molecules tend to rise and colder molecules tend to fall within the container, due to their different densities, which are proportional to their temperature. This fluid flow is called “convection”. The convection effect tends to negate the effect of energy transport from the top to the bottom due to gravity. In accordance with the invention, it is therefore helpful optionally to fill the container with, for example, a mass of very fine fibers 6, such as, for example, glass wool (Fiberglas®), natural or plastic fibers (solid or hollow), powder, foam, or small solid or hollow spheres (e.g., made of plastic, metal, or glass), in order to reduce convection currents and radiation to a minimum. This might not be necessary when using highly viscous liquids like heavy oils, petroleum jelly or gelatin.

When using a gas, it is helpful also optionally to reduce the pressure in container 2 to such a degree that the free path length of the molecules therein is greater than the inner dimensions of the container. Thus, the molecules fly from wall to wall, without hitting any other molecule. For example, if the pressure is reduced, e.g., to 0.00001 mbar, the free path for air at 20 degrees C. increases to 6 meters, and thus the molecules fly directly from one wall to the other in a container with a height of 1 meter.

In another embodiment of the invention, container 2 containing a gas with a lower pressure, also called a rarified gas, is divided by a number of horizontally arranged thin films (such as, e.g., films comprising thin metal or plastic). Using, for example, ten evenly spaced apart films within the container, allows one to increase the pressure of the gas to 0.0001 mbar, thereby reducing the free path to 0.6 meters. The maximum vertical length of the free space is thus only 0.1 meters, and the molecules therein then fly directly from wall to wall. The higher pressure also has the advantage that the amount of energy transported from the upper to the lower wall increases in proportion with the pressure.

The opposite, namely to increase the gas pressure can have a beneficial effect, as the amount of energy transferred from the top of the container to its bottom increases proportional to the gas pressure.

The temperature difference between the top and the bottom can be calculated, as it is proportional to the difference of the potential energy of the molecules at the top and at the bottom, as follows:

E=W×H where E is potential energy, W is weight, and H is vertical distance (i.e. height).

This amount of energy equals the temperature increase of the mass in question:

E=M×c(Gr)×ΔT, where c(Gr) is the specific heat c(for gases cv) divided by n where n is the number of freedom of degrees, ΔT is the temperature difference between the two ends of the column, and M is the mass of the molecules.

Therefore:

W×H=M×c(Gr)×ΔT or

$$Δ T = \frac{W}{M} \times \frac{H }{c ( G r ) } with \frac{W}{M} = g$$

$$Δ T = - g \times \frac{H}{c ( G r )}$$

(minus as gravity acts against direction of H)

Using the above formula, one can calculate the temperature differences for various atoms and molecules. Table 1, below, gives the results for a height of one meter for various materials.

TABLE 1

| Material | Aluminum | Lead | Water | Glass | Mercury | Xenon | Iodine Gas | Air |
|---|---|---|---|---|---|---|---|---|
| Specific heat | 900 | 130 | 4185 | 800 | 140 | 160 | 140 | 718 |
| (m²/sec², ° C.) | | | | | | | | |
| ΔT (° C.) | −0.009 | −0.08 | −0.04 | −0.009 | −0.06 | −0.311 | −0.355 | −0.07 |

FIG. 1 shows the simplest form of the invention. Enclosure 2, preferably comprising aluminum with a thickness of about 2 cm, has an interior or central chamber 12, which is filled with a gas or liquid. This massive aluminum enclosure helps to equalize the temperature of the inside surface of the enclosure as much as possible. The enclosure is insulated from its surroundings by an insulating material 3, such as, for example, polystyrene foam in a thickness of about 50 cm. Preferably, chamber 12 is filled with a mass of very fine solid or hollow fibers 6, such as, for example, glass wool (e.g., Fiberglas®), natural fibers, or other materials such as foam, powder, or small solid or hollow spheres (e.g., comprising plastic, glass or metal), in order to reduce convection currents and radiation effects to a minimum. The fibers are optionally used to help avoid convection currents in the enclosed gas or liquid, as this tends to decrease the creation of the temperature difference, upon which the present invention is based.

Referring again to FIG. 1, thermocouple 4 measures the temperature difference between the top and the bottom (or some other vertical segment) of the thermal differential element (i.e., gas in this example). Wires 5 transfer the voltage output (V+/−) from thermocouple 4 to the outside of chamber 12. For example, using a Type E thermocouple, in which one leg of the thermocouple is made from copper/nickel and the second leg is made from nickel/chromium, the system of the invention yields a voltage of about 70 mV per 100 degrees C. In order to increase the usefulness of this voltage, one optionally employs a large number of thermocouples arranged in sequence, such as in a thermopile, as shown schematically in FIGS. 2 and 3. Thus, using 100 thermocouples in sequence, the voltage in example 1 increases to 7V per 100 degrees C.

As predicted by Table 1, one measures a temperature difference between the top and the bottom for the enclosure with a vertical height of 1 meter of about 0.01 to 0.3 degrees C. In this case, the temperature differential depends on the relative weights and weight distribution of the gas molecules, the glass wool, and the material of the enclosure. The choice of such materials is within the skill of one of ordinary skill in the art, based on the teachings herein, and determines the extent of the temperature difference obtained in the system of the present invention.

Referring to FIG. 2, a lead rod 1 with a diameter of about 5 cm and a length of about 100 cm is arranged in a vertical position within enclosure 2, thereby forming the temperature differential element of the invention. The enclosure of this example is built with a diameter of about 20 cm and a height of about 120 cm, and the space between rod 1 and enclosure 2 is filled with loose glass fibers 6.

Although the height of the chamber in this example is shown as being much larger than the width or depth, such a limitation is not required of the invention. The height of the container simply determines the maximum possible temperature differential, whereas the total mass of the temperature difference element determines the maximum possible energy transfer from the top to the bottom.

The use of lead rod 1 in FIG. 2, as opposed to a gas or liquid as shown in FIG. 1, can be predicted from Table 1 to produce a larger temperature differential, due to the smaller specific heat of lead as compared to a typical gas.

A further increase in the usefulness of the invention optionally is obtained by increasing the length of rod 1 and by combining a number of enclosures 2 in one installation.

Alternatively, if the mass is a solid as shown in FIG. 3, the space inside enclosure 2 can be evacuated, and the inside surfaces 7 are optionally made highly reflective to radiation, in order to insulate rod 1 from the surrounding enclosure and thereby avoid heat transfer between them as much as possible.

As shown in FIG. 3, the apparatus of the invention optionally is surrounded by a housing 8, which preferably is kept at a relatively constant temperature (e.g., about +/−0.5 degrees C.) through a thermostatically controlled heating system 9, which optionally is powered from outside the surrounding area by electrical connections 10, liquid flow, or like means. Improved thermal insulation also is obtained optionally by evacuating the space or by dividing the space in two parts, as shown in FIG. 3, one being filled with insulation 3 and one being evacuated 11.

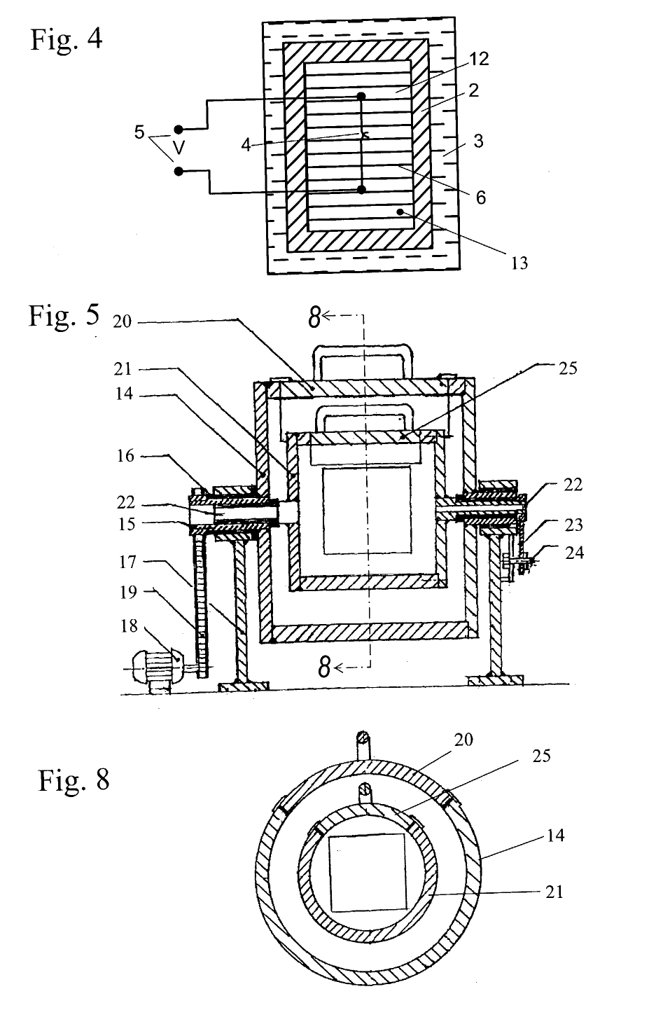

It is also within the scope of the invention to reduce the pressure in chamber 12 to, for example, 0.0001 mbar, using a rarified gas or gases with a free path greater than the inner dimensions of the container. Referring to FIG. 4, container 2 containing a gas with a lower pressure, also called a rarified gas, is divided by a number of horizontally arranged thin films 13 (such as, e.g., films comprising thin metal or plastic). Using, for example, ten evenly spaced apart films within the container, allows one to increase the pressure of the gas to 0.0001 mbar, thereby reducing the free path to 0.6 meters. The maximum vertical length of the free space is thus only 0.1 meters, and the molecules therein then fly directly from wall to wall. The higher pressure also has the advantage that the amount of energy transported from the upper to the lower wall increases in proportion with the pressure.

It is further within the scope of the present invention optionally to expose the enclosure to any constant field, be it gravitational, electrical or electromagnetic. Any known solid, liquid or gaseous material optionally is used for creating these temperature differences, but those with a low specific heat and/or a high number of degrees of freedom are most advantageous.

In order to use the method of the invention in accordance with the preferred embodiment, the surroundings of the apparatus of the invention preferably have a temperature as constant as possible. This generally is difficult to attain, as in any space or room, there is typically a temperature distribution over height of about 1 degree C. per meter. In order to alleviate this problem, in a further embodiment of the invention, an apparatus in accordance with FIGS. 5 and 8 optionally is used. Referring to FIGS. 5 and 8, an embodiment of the present invention comprises a drum-like enclosure 14 that has a horizontal axle 15. The axle is held in bearings 16 supported by stand 17. A motor 18 (or similar suitable means) is connected through chain drive 19 with axle 15, and turns drum 14 around its horizontal axle at a rate of about 1-10 times per minute. Drum 14 preferably comprises a metal with a high heat conductivity, such as, for example, aluminum, and preferably is relatively thick, such as, for example, about 3 cm, such that drum 14 has a relatively small temperature difference within its body. The rotation of drum 14 tends to equalize the temperature difference of its surroundings, typically from about 1 degree C. per meter of height to a very small temperature difference, thereby increasing the efficiency of the apparatus.

Drum 14 typically has a cover 20 (or similar suitable means) for allowing access to container 21. Container 21, in turn, has its own horizontal axle 22, which is mounted inside axle 15 in such a way that it is able to remain stationary, while drum 14 rotates around it. Container 21 is held in a stationary vertical position via arm 23, which optionally is fixed in its position through a removable bolt 24 (or similar suitable means) bolted to stand 25. The apparatus in accordance with FIGS. 1-4 optionally is installed inside container 21, through covers 20 and 26. Due to the rotation of drum 14, container 21 shows a temperature difference of only about 0.001 degrees C., as measured over a height of about 1 meter between the top and the bottom of container 21. As a result, the temperature difference due to the effect of gravity inside container 2, in accordance with FIGS. 1-4, is much more pronounced, as the temperature differential is thus not negatively affected by a temperature differential within the room in which the apparatus of the invention is located. The axle on one side of container 21 is optionally hollow, such that any thermocouple wires coming from container 2 can be led to the outside thereof, to be connected to a voltmeter, generator, or similar suitable device.

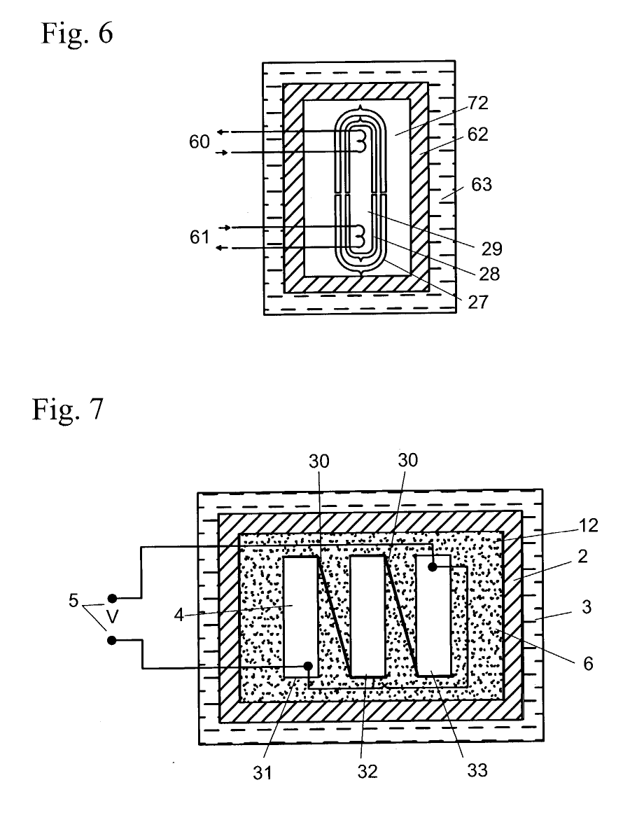

FIG. 6 shows the optional use of Dewar glasses 27 and 28. Dewar glasses are two-walled glass containers, which are very well known in the prior art. The space between the two glass walls typically is evacuated to a pressure of about 0.001 mbar. This results in a very low heat conductivity between the two walls. Therefore Dewar glasses typically are used to store liquids that would normally exist in the gaseous state at ambient temperature. In accordance with the invention, the Dewar glasses form the elongated enclosure, and enclose the interior chamber 29, which is extremely well insulated from the area outside the enclosed system. The Dewars can be placed in a housing 62, preferably covered in insulation 63, and the space 72 between the outer Dewar 27 and the housing 62 can be evacuated or filled with foam, solid or hollow fibers or small particles, such as, for example, solid or hollow spheres or sand.

FIG. 6 shows the use of heat exchangers 60 and 61, in place of the thermocouples shown in other figures. This is an alternative method of extracting energy from the mass, in the form of heat or cold, by passing a heat-exchange fluid through the exchanger. Heat exchanger 60 is the colder, heat exchanger 61 the warmer exchanger. The energy from exchanger 60 or 61 could be used directly to warm or cool something, or used to power a refrigerator, or provide heat to drive a heat-powered device such as a Stirling cycle engine. In this arrangement the temperature difference element would act like the pump in a heat pump, transferring energy from the heat exchanger 60 to the heat exchanger 61.

To use the temperature difference to create electrical energy or to use it through a heat exchanger producing a warm and/or cold liquid, it is advantageous to have a temperature difference as high as possible. To reach a higher temperature difference by increasing the height of the temperature differential element is often not possible due to space limitations. In accordance with the invention a number of elements can be combined in one housing 3 as shown in FIG. 7 for three elements. They are arranged in sequence to each other by connecting the cold top of element 31 with the warm bottom of element 32 and the warm top of this element with the bottom of element 33. The connecting element 30 can be a metal rod with a high heat conductivity, e. g. made from copper or silver, or it can be a temperature differential element filled with a gas having a smaller temperature difference per meter of height than the elements 31, 32, and 33. Through this temperature difference between the bottom of element 31 and the top of element 33 is greater than the temperature difference of one element alone.

Accordingly, it is to be understood that the embodiments of the invention herein described are merely illustrative of the application of the principles of the invention. Reference herein to details of the illustrated embodiments are not intended to limit the scope of the claims, which themselves recite those features regarded as essential to the invention.

What is claimed is:

1. A method to create a temperature difference within a mass of solid, liquid or gas, comprising the steps of:
a) providing a closed system in the form of an elongated insulated container having an interior; and
b) enclosing the mass, comprising a temperature difference element, within the interior of the container in a vertical arrangement.

2. The method of claim 1, further comprising the step of extracting energy from the temperature difference element.

3. The method of claim 2, in which the step of extracting energy comprises providing a thermocouple along a vertical segment of the temperature difference element, and energy is extracted in the form of electricity generated by the thermocouple from a temperature difference along the vertical segment.

4. The method of claim 2, in which the step of extracting energy comprises the steps of providing a heat exchanger in the interior and passing a heat-exchange fluid through the exchanger, and energy is extracted in the form of heat.

5. The method of claim 1, further comprising the step of filling the interior of the container with a permeable material, such that the effects of convection and radiation in the mass are reduced.

6. The method of claim 5, in which the permeable material is selected from a group comprising solid glass fibers, hollow glass fibers, powder, solid spheres, hollow spheres, sand and foam.

7. The method of claim 1, in which the mass is a solid, further comprising the step of evacuating the interior of the container.

8. The method of claim 1, further comprising the steps of surrounding the container with a rotatable drum, and rotating the drum.

9. The method of claim 1, further comprising the step of mounting the container on a pivot, such that the container can be inverted.

10. An apparatus to create a temperature difference within a mass of solid, liquid or gas, comprising:
an elongated container comprising a closed insulated chamber with an interior;
a mass comprising a temperature difference element disposed vertically inside the interior of the closed chamber.

11. The apparatus of claim 10, further comprising a thermocouple arranged along a vertical segment of the temperature difference element, such that energy is extracted in the form of electricity generated by the thermocouple from a temperature difference along the vertical segment.

12. The apparatus of claim 10, further comprising a heat exchanger in the interior, such that energy is extracted in the form of heat.

13. The apparatus of claim 10, in which the interior of the container is filled with a permeable material, such that the effects of convection and radiation in the mass are reduced.

14. The apparatus of claim 13, in which the permeable material is selected from a group comprising solid glass fibers, hollow glass fibers, powder, solid spheres, hollow spheres, sand and foam.

15. The apparatus of claim 10, in which the mass is a solid and the interior of the container is evacuated.

16. The apparatus of claim 10, further comprising a rotatable drum surrounding the elongated insulated chamber.

17. The apparatus of claim 10, in which the elongated insulated container is mounted on a pivot, such that the container can be inverted.

18. The apparatus of claim 10, further comprising a housing surrounding the elongated container.
